(19) United States
(12) Patent Application Publication
(10) Pub. No.: US 2006/0046441 A1
(43) Pub. Date: Mar. 2, 2006

(54) Method of monitoring selectivity of selective film growth method, and semiconductor device fabrication method

(76) Inventors: Kiyotaka Miyano, Fujisawa-Shi (JP); Akihito Yamamoto, Kanagawa-Ken (JP); Yoshihiko Saito, Yokosuka-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/211,745

(22) Filed: Aug. 26, 2005

(30) Foreign Application Priority Data
Sep. 1, 2004 (JP) 2004-254722

(51) Int. Cl. H01L 21/20

(52) U.S. Cl. 438/479

(57) ABSTRACT

According to the present invention, there is provided a selectivity monitoring method in a selective film growth method of selectively growing a film in a predetermined region on a semiconductor substrate, comprising: selectively growing the film on a surface of the semiconductor substrate while measuring temperature of the surface of the semiconductor substrate by at least one pyrometer placed in a non-contact state above the surface of the semiconductor substrate; and determining that selectivity of the growth of the film has decreased, when the temperature changes from a predetermined value or changes from a predetermined angle in a graph showing change of the temperature during film formation.

### CROSS REFERENCE TO RELATED APPLICATION

This application is based upon and claims benefit of priority under 35 USC §119 from the Japanese Patent Application No. 2004-254722, filed on Sep. 1, 2004, the entire contents of which are incorporated herein by reference.

### BACKGROUND OF THE INVENTION

The present invention relates to a method of monitoring the selectivity of a selective film growth method, and a semiconductor device fabrication method.

As micropatterning advances to increase the density and processing speed of a complementary field-effect transistor (CMOSFET), the technique of selectively epitaxially growing a semiconductor film containing, e.g., Si or SiGe as a diffusion layer is being extensively studied, in order to suppress the short-channel effect or introduce the silicide technique for new materials such as NiSi.

This selective film growth technique has a high utility value because a desired film can be grown in a desired region, and is expected to be widely applied to portions other than diffusion layers of a semiconductor device.

On the other hand, operation errors of a device may occur if a film is formed in an undesired region.

It is, however, impossible to determine, during film formation, whether the selectivity is maintained, i.e., whether growth nuclei are formed on an undesired region, or whether a film is growing on an undesired region.

More specifically, the conventionally performed methods are only monitoring by which a wafer on which a film is formed is observed with a microscope, and monitoring by which a test piece wafer on which no devices are formed is used as a monitoring wafer, and the wafer on which a film is formed is observed with a surface defect tester using a laser beam or the like.

In the former method, however, it is unrealistic to perform plane SEM observation over the entire wafer surface, and micronuclei may be overlooked when an optical microscope is used. In the latter method, the result of selectivity monitoring on the test piece containing no devices does not accurately reflect the status on an actual wafer containing devices.

From these points, no conventional techniques can realize selectivity monitoring during film formation although it is desirable.

References disclosing the conventional monitoring techniques concerning film formation are as follows.

Reference 1: Japanese Patent Laid-Open No. 6-220643

Reference 2: Japanese Patent Laid-Open No. 1-83124

### SUMMARY OF THE INVENTION

According to one aspect of the present invention, there is provided a selectivity monitoring method in a selective film growth method of selectively growing a film in a predetermined region on a semiconductor substrate, comprising:

selectively growing the film on a surface of the semiconductor substrate while measuring temperature of the surface of the semiconductor substrate by at least one pyrometer placed in a non-contact state above the surface of the semiconductor substrate; and

determining that selectivity of the growth of the film has been lost, when the temperature changes from a predetermined value or changes from a predetermined angle in a graph showing change of the temperature during film formation.

According to one aspect of the present invention, there is provided a semiconductor device fabrication method of selectively growing a film in a predetermined region on a semiconductor substrate, comprising:

selectively growing the film on a surface of the semiconductor substrate by using an initial value of a preset film formation condition, while measuring temperature of the surface of the semiconductor substrate by at least one pyrometer placed in a non-contact state above the surface of the semiconductor substrate;

determining that selectivity of the growth of the film has been lost, when the temperature changes from a predetermined value or changes from a predetermined angle in a graph showing change of the temperature during film formation, and changing the film formation condition; and

selectively growing the film on the surface of the semiconductor substrate by using the changed film formation condition, while measuring the emissivity of the surface of the semiconductor substrate by using the pyrometer.

According to one aspect of the present invention, there is provided a semiconductor device fabrication method of selectively growing a film in a predetermined region on a semiconductor substrate, comprising:

selectively growing the film on a surface of the semiconductor substrate by using a preset film formation condition, while measuring temperature of the surface of the semiconductor substrate by at least one pyrometer placed in a non-contact state above the surface of the semiconductor substrate, measuring an incubation period before nuclei are formed on an unselected region, and also measuring a film thickness A of the film formed on a selected region during the incubation period;

calculating the number M of cycles by dividing a desired film thickness T by the film thickness A; and

performing a film formation process by repeating, by the number M of cycles, performing film formation until the incubation period expires, stopping the film formation, and selectively growing the film on the surface of the semiconductor substrate by changing the film formation condition.

### BRIEF DESCRIPTION OF THE DRAWINGS

FIG. 1 is a perspective view showing the arrangement of an apparatus used in selective film growth methods and their monitoring methods according to the first to third embodiments of the present invention;

FIG. 2 is a cross sectional view of elements showing a predetermined step of the selective film growth method according to the first embodiment of the present invention;

FIG. 3 is a cross sectional view of elements showing a predetermined step of the selective film growth method according to the first embodiment;

FIG. 4 is a cross sectional view of elements showing a predetermined step of the selective film growth method according to the first embodiment;

FIG. 5 is a graph showing temperature changes during film formation;

FIG. 6 is a flowchart showing the sequence of processing in a film formation method according to the second embodiment of the present invention;

FIG. 7 is a graph showing the relationship between the film formation time and film thickness in a film formation method according to the third embodiment of the present invention; and

FIG. 8 is a flowchart showing the sequence of processing in the film formation method according to the third embodiment.

### DETAILED DESCRIPTION OF THE INVENTION

Embodiments of the present invention will be described below with reference to the accompanying drawings.

### (1) First Embodiment

A method of monitoring the selectivity during selective film growth according to the first embodiment of the present invention will be described below.

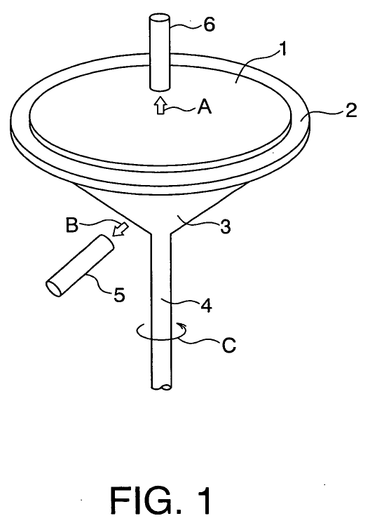

FIG. 1 shows the arrangement of an apparatus used in the monitoring method according to the first embodiment. In this arrangement, a pyrometer for selectivity monitoring is placed in a CVD apparatus which performs single wafer chemical vapor deposition (CVD) used in selective growth of a typical semiconductor film.

A semiconductor wafer 1 is placed on a susceptor 2, and a rotating shaft 4 connected to the susceptor 2 is rotated in the direction of an arrow C by a rotary mechanism (not shown).

To measure the internal temperature of the CVD apparatus, a pyrometer 5 faces a backside 3 of the susceptor 2. The pyrometer 5 measures the emissivity from the backside 3 of the susceptor 2, as indicated by an arrow B.

In the first embodiment, a pyrometer 6 is additionally placed at a predetermined distance above the upper surface of the semiconductor wafer 1. The pyrometer 6 measures the emissivity from the surface of the semiconductor wafer 1 as indicated by an arrow A, and the emissivity is converted into the temperature.

The emissivity changes in accordance with the material on the surface of a portion to be measured. Accordingly, by measuring the emissivity while a predetermined film is formed on the surface of the semiconductor wafer 1, the size of the area of the region where the film is being formed can be monitored.

Referring to FIG. 1, one pyrometer 6 is positioned above the center of the upper surface of the semiconductor wafer 1. However, a plurality of pyrometers 6 may also be arranged above the upper surface of the semiconductor wafer 1. The temperatures of a plurality of portions of the semiconductor wafer 1 can be measured by thus arranging a plurality of pyrometers 6. On the surface of the semiconductor wafer 1, a film cannot be evenly formed in a central region and peripheral region in some cases. In a case like this, since the emissivities, that is temperature of a plurality of portions are measured and this reduces the dependence on each measurement portion, the temperature of the whole semiconductor wafer 1 can be measured without any bias.

A method of performing a film formation process by using the apparatus as described above will be explained below.

Especially in a logic device among other semiconductor devices, many circuits are formed by combining many transistor regions and many element isolation regions for isolating the transistor regions.

For highly micropatterned advanced logic devices, it is desirable to use the selective growth technique which selectively epitaxially grows a semiconductor film containing Si, SiGe or SiC only in a diffusion layer region, in order to, e.g., suppress the short-channel effect and decrease the resistance of a suicide. In-process strain technology is also materialized by selective growth.

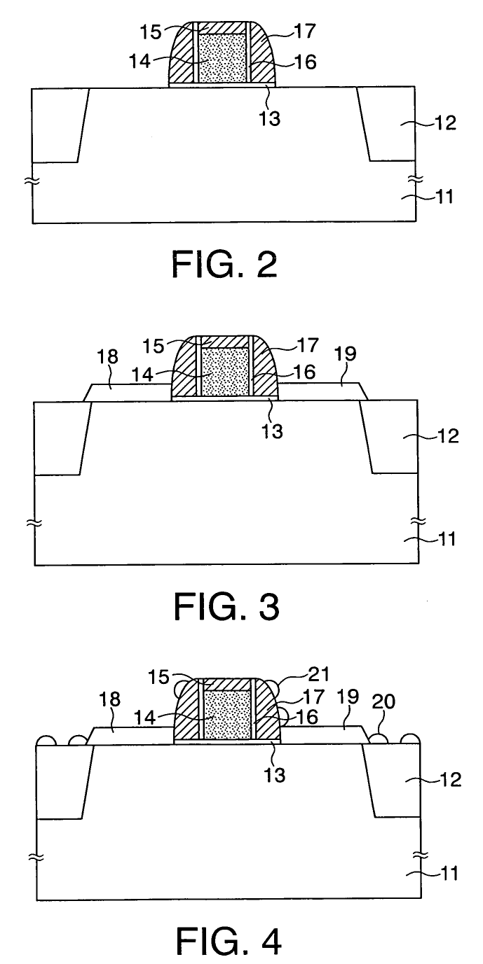

FIG. 2 shows a portion of the sectional shape of a semiconductor wafer before a semiconductor film is epitaxially grown.

In the surface portion of a semiconductor wafer 11,.element isolation regions 12 such as STI (Shallow Trench Isolation) for isolating an element region are formed. On the surface of the element region, a polysilicon film 14 and cap silicon nitride film 15 are formed into the shape of a gate electrode via a gate insulating film 13. A silicon oxide film 16 and sidewall silicon nitride film 17 are formed on the side surfaces of the polysilicon film 14 and silicon nitride film 15.

As processing before selective growth, the semiconductor wafer 11 in this stage is processed by using, e.g., a dilute hydrofluoric acid solution, thereby removing a thin oxide film such as a native oxide film formed on the exposed substrate surface of the semiconductor wafer 11.

Then, the semiconductor wafer 11 is loaded into a CVD apparatus, and heat-treated in a hydrogen ambient at a temperature of, e.g., 900° C., thereby removing a native oxide film formed on the substrate surface during transfer.

Subsequently, film formation is continuously performed in the same apparatus for a few minutes at a temperature of, e.g., about 800° C. and a total pressure of, e.g., about 50 (Torr), while SiH₂Cl₂=500 (cc), HCl=150 (cc), and H₂=20,000 (cc) are supplied as ambient gases.

By this epitaxial growth, a single-crystal silicon film having a thickness of a few tens of nm is selectively formed only on a diffusion layer where the substrate surface is exposed. As a consequence, a structure having elevated diffusion layers (elevated source and drain layers) 18 and 19 as shown in FIG. 3 can be obtained.

In a CMOS arrangement, after a single-crystal silicon film in which no impurity is doped is formed, an impurity corresponding to each conductivity type is doped. However, when only a P- or N-type transistor is to be formed, a single-crystal silicon film in which an impurity is doped beforehand may also be formed.

As shown in FIG. 4, the selectivity sometimes is lost to form nuclei 20 and 21 on unselected regions, i.e., on the element isolation regions 12 and the sidewall silicon nitride film 17. If the nuclei 20 and 21 form, a silicon film is formed on the unselected regions as well.

In this case, this transistor shortcircuits to an adjacent transistor beyond the element isolation region 12. Consequently, these transistors can no longer operate electrically independently of each other, or the gate to the source/drain path shortcircuit in the transistor.

To avoid an event like this, in the first embodiment, the temperature of the surface of the semiconductor wafer 11 is measured by the pyrometer 6 while selective film growth is performed. It is determined that the selectivity is maintained if the temperature maintains a predetermined value, and that the selectivity has been lost if the temperature changes from the predetermined value during the course of film growth. In this manner, the selectivity during film growth can be monitored. Otherwise, it is determined that the selectivity has been lost, if the temperature changes from a predetermined angle in a graph showing change of the temperature during film formation

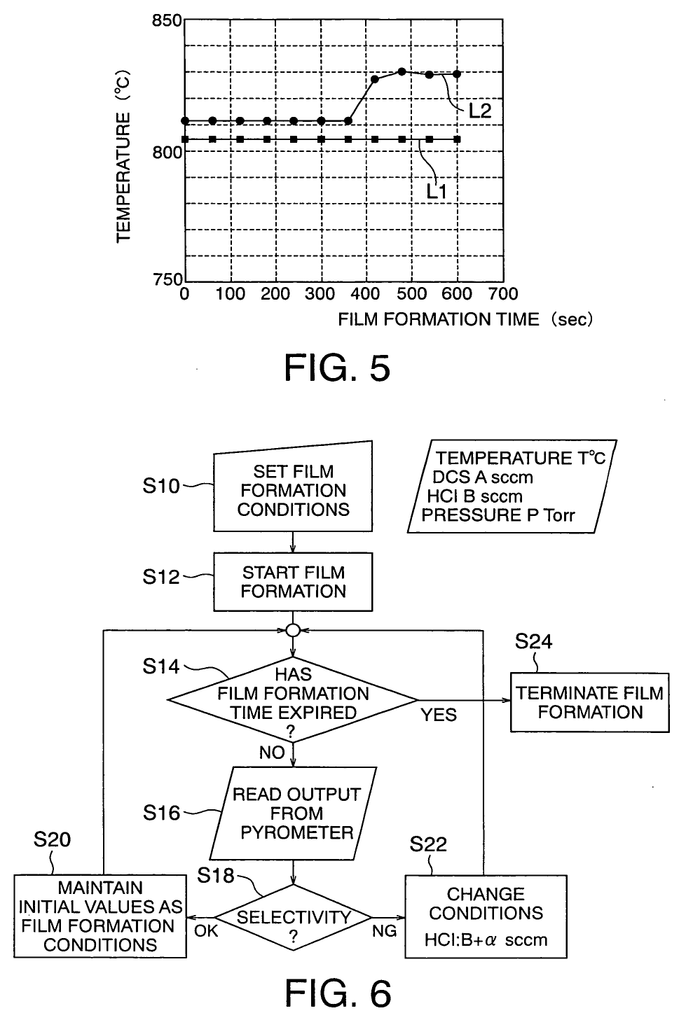

FIG. 5 shows a measurement curve L1 obtained by measuring the emissivity of the backside of the susceptor by the pyrometer 5 and converting the measured emissivity into a temperature, and a measurement curve L2 obtained by measuring the emissivity of the surface of the semiconductor wafer 11 by the pyrometer 6 and converting the measured emissivity into a temperature.

As indicated by the measurement curve L1, the internal temperature of the CVD apparatus is constant at about 805 (° C.) regardless of the passage of the film formation time. On the other hand, as indicated by the measurement curve L2, the emissivity, that is the temperature on the surface of the semiconductor wafer 11 rises when a film formation time of about 370 (sec) has passed.

While an epitaxial film is selectively grown only on the exposed substrate surface of the semiconductor wafer 11, the film is formed only on semiconductor materials having substantially the same emissivity, that is the same temperature, and no semiconductor film is grown on insulating films having different emissivities, i.e., that is different temperatures, on the element isolation regions 12 and sidewall silicon nitride film 17. Accordingly, the selectivity is maintained while the emissivity, that is the temperature maintains a predetermined value.

If the emissivity is lost during selective growth, a semiconductor film is also formed on the insulating films, and this makes the temperature of the whole semiconductor wafer 11 changed from than the predetermined value.

In the example shown in FIG. 5, when a film formation time of about 370 (sec) has passed, the output value from the pyrometer 6 changes from a predetermined value, i.e., rises from 812 (° C.) to 830 (° C.) as a temperature. This demonstrates that the selectivity has been lost at that time.

In the first embodiment as described above, the selectivity can be monitored during film formation.

Note that the decrease in selectivity may also be determined on the basis of the fact that the slope of the temperature is substantially “0” while the selectivity is maintained, and a slope larger or smaller than a predetermined value is produced if the selectivity is lost.

### (2) Second Embodiment

The second embodiment of the present invention relates to a semiconductor device fabrication method which further includes, in addition to the monitoring of the selectivity, that is temperature during film formation in the first embodiment, an arrangement for feeding the result of monitoring back to the film formation conditions.

The apparatus configuration including a pyrometer for monitoring the emissivity of the surface of a semiconductor wafer during film formation is the same as the first embodiment.

A flowchart in FIG. 6 shows a sequence for feeding the selectivity monitoring result back to the film formation conditions according to the second embodiment.

In step S10, the film formation conditions are set. The film formation conditions are variable parameters, and their examples are the temperature (T), the flow rate of a source gas (e.g., DCS (DiChloroSilane)=SiH₂Cl₂) for film formation, the flow rate of an etching gas (e.g., HCl) for preventing the formation of nuclei on unselected regions or removing the formed nuclei, a carrier gas (e.g., H₂) for evenly dispersing the source gas and etching gas in a CVD apparatus, and the pressure (P).

In step S12, film formation is started.

In step S14, whether a preset film formation time has expired is checked. If NO in step S14, the flow advances to step S16.

In step S16, the output from the pyrometer during film formation is read.

In step S18, whether the selectivity is maintained is checked on the basis of the output value from the pyrometer. If the selectivity is high, the flow advances to step S20.

In step S20, the values initially set as the film formation conditions are maintained, and the flow returns to step S14.

If in step S18 it is determined on the basis of the output value from the pyrometer that the selectivity has been decreased, the flow advances to step S22.

In step S22, the film formation conditions are changed. To increase the selectivity, it is possible to change, e.g., the ratio of the source gas flow rate to the etching gas flow rate. That is, the etching gas flow rate is increased from B (sccm) to B+α (sccm), or the source gas flow rate is decreased from A (sccm) to A−β (sccm).

It is also possible to change the temperature from C (° C.) to C−γ (° C.). The pressure is not usually changed because it presumably has no large influence on the selectivity.

After the film formation conditions are changed, the flow returns to step S14 to continue the film formation process.

If, after the film formation conditions are changed, it is determined in step S18 that the selectively has been improved, the flow advances to step S20 to return the film formation conditions to the initial values.

If the film formation conditions changed in order to increase the selectivity are maintained, no desired film thickness is reached in many cases even when the film formation time has expired. Therefore, it is necessary to obtain a desired film thickness by returning the film formation conditions to the initial values.

If the film formation time has expired in step S14, the flow advances to step S24 to terminate the film formation process.

In the second embodiment as described above, the selectivity is monitored during film formation. If it is determined that the selectivity has decreased, the film formation conditions are changed, e.g., the flow rate of the etching gas is increased, so that the selectivity is improved. In this way, lost of selectivity is prevented by removing nuclei formed on unselected regions.

This makes it possible to readily obtain an elevated source/drain structure in which no nuclei are formed on unselected regions such as element isolation regions and gate electrode side walls.

### (3) Third Embodiment

The third embodiment of the present invention relates to a semiconductor device fabrication method which further includes an arrangement for controlling the film thickness, in addition to the arrangement for monitoring in the first embodiment.

When the film formation conditions and the surface state of the substrate are constant, a so-called incubation period (latent period) from the start of film formation to the moment the selectivity decreases after the film formation is performed with a high selectivity is constant.

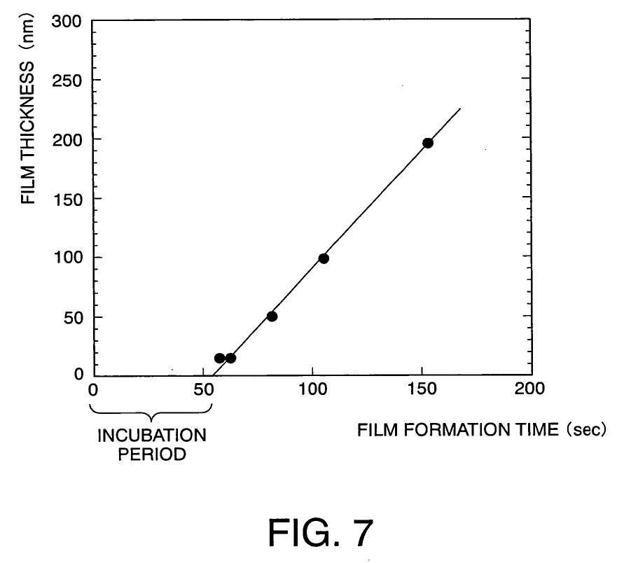

FIG. 7 shows the relationship between the film formation time and the film thickness.

The film formation conditions were that DCS (flow rate: 250 cc/min) was used as a source gas, HCl (flow rate: 150 cc/min) was used as an etching gas, H₂ (flow rate: 20,000 cc/min) was used as a carrier gas, the film formation temperature was 800 (° C.), and the pressure was 10 (Torr).

In the film formation time on the abscissa, the time (the segment of the abscissa) elapsed from the state in which the film formation was started to the moment the film thickness rose is the incubation period.

This incubation period means that no growth occurs on the silicon oxide, silicon nitride or any other dielectric film during this period. Accordingly, measuring the incubation period shown in FIG. 7 is equivalent to monitoring the moment nucleation occurs after the incubation period has expired in an unselected region where the silicon oxide film is formed. That is, a constant latent period is monitored while the film formation conditions and the surface structure are constant.

As shown in FIG. 7, the incubation period was 60 (sec) when the film formation conditions of the third embodiment were used and the film was formed on the surface of the silicon oxide film on the substrate. Also, when 60 sec elapsed from the start of film formation, the film thickness of the epitaxial growth layer selectively formed on a diffusion layer where the silicon substrate was exposed was 15 (nm).

Accordingly, assuming that a film formation step corresponding to the incubation period from the start of film formation to the moment the selectivity decreases is one cycle, the film formation amount on the selected region per cycle is 15 (nm). After that, film formation is performed by changing the film formation conditions described above, in order to increase the decreased selectivity. By counting a plurality of cycles each of which is a pair of these steps, the film thickness can be controlled for every 15 (nm) as a unit step.

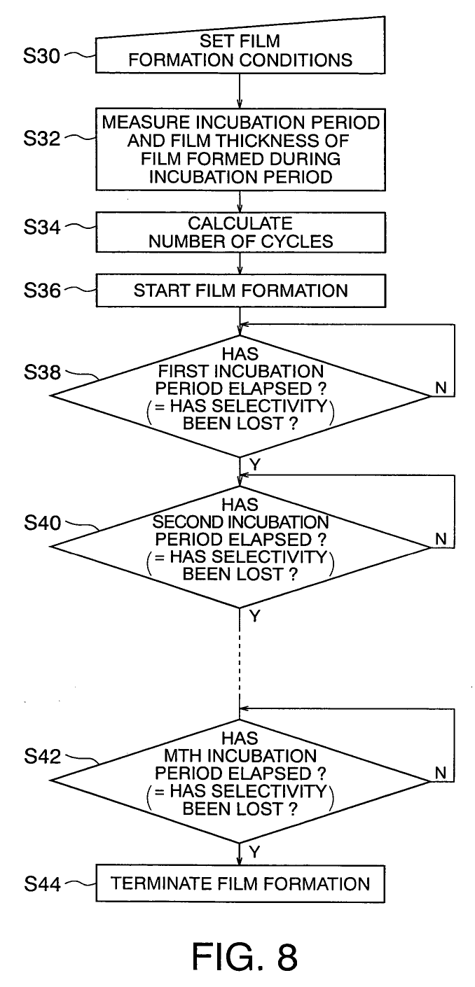

FIG. 8 shows the sequence of processing in the fabrication method according to the third embodiment.

In step S30, the film formation conditions are set. As described above, the film formation conditions include, e.g., the flow rates of the source gas and etching gas, the film formation temperature, and the pressure.

In step S32, the incubation period is measured. First, as described above, the incubation period from the start of film formation to the moment nucleation occurs on an unselected region is measured. In addition, a film thickness A (nm) of a film formed on the selected region before the incubation period elapses is measured.

In step S34, the number M of cycles is calculated by dividing a desired film thickness T (nm) of a film to be formed on the selected region by the film thickness A (nm) formed during one incubation period.

In step S36, a film formation process is started.

In step S38, whether the first incubation period has elapsed is checked by measuring the selectivity. If YES in step S38, the flow advances to step S40. In step S38, a film having a premeasured, predetermined film thickness A×1 (nm) is formed on a selected region. After that, film formation is performed by changing the film formation conditions set in step S30 in order to increase the decreased selectivity.

In step S40, film formation is started under the film formation conditions set in step S30, and whether the second incubation period has elapsed is checked. If YES in step S40, the flow advances to the next step (not shown). In steps S38 and S40, a film having a film thickness A×2 (nm) is formed on the selected region. After that, film formation is performed by changing the film formation conditions set in step S30 in order to increase the decreased selectivity.

In step S42, film formation is started under the film formation conditions set in step S30, and whether the Mth incubation period has elapsed is checked. If YES in step S42, the flow advances to step S44 to terminate the film formation process. As a consequence, a film having a film thickness A×M (nm) is finally formed on the selected region.

In the third embodiment as described above, the film thickness is controlled by the number of cycles before the selectivity decreases, on the basis of the fact that when the film formation conditions and the substrate structure are constant, the incubation period from the start of film formation to the moment the selectivity decreases is constant, and the film thickness of a film formed on a selected region during this period is also constant. That is, film formation conditions are set, an incubation period and the film thickness of a film formed on a selected region before the incubation period has elapsed are premeasured under the set conditions, and film formation is performed over a plurality of cycles until a desired film thickness is obtained. In this way, the film thickness can be controlled with high accuracy.

Each of the above embodiments is merely an example, and does not limit the present invention. For example, the film formation conditions described above are examples, and can be freely set where necessary.

The semiconductor substrate is not limited to Si, and need only contain at least one of Si, Ge and C.

A film to be grown need only be a single-crystal film, polycrystalline film, or amorphous film containing at least one of Si, Ge, and C.

As a source gas, it is also possible to use, e.g., Si₂H₆, SiH₄, Si₃H₈, SiHCl₃, or Si₂Cl₆, instead of DCS (═SiH₂Cl₂), in accordance with a film to be grown. As an etching gas, HCl, Cl₂, HBr, Br₂, HF, F₂, SF₆, or the like may also be used. As a carrier gas, an inert gas such as N₂ or He may also be used instead of H₂.

What is claimed is:

1. A selectivity monitoring method in a selective film growth method of selectively growing a film in a predetermined region on a semiconductor substrate, comprising:
selectively growing the film on a surface of the semiconductor substrate while measuring temperature of the surface of the semiconductor substrate by at least one pyrometer placed in a non-contact state above the surface of the semiconductor substrate; and
determining that selectivity of the growth of the film has decreased, when the temperature changes from a predetermined value or changes from a predetermined angle in a graph showing change of the temperature during film formation.

2. A method according to claim 1, wherein the film is grown by single wafer chemical vapor deposition.

3. A method according to claim 1, wherein the emissivity is measured by further using a second pyrometer which faces a backside of a susceptor on which the semiconductor substrate is placed.

4. A semiconductor device fabrication method of selectively growing a film in a predetermined region on a semiconductor substrate, comprising:
selectively growing the film on a surface of the semiconductor substrate by using an initial value of a preset film formation condition, while measuring temperature of the surface of the semiconductor substrate by at least one pyrometer placed in a non-contact state above the surface of the semiconductor substrate;
determining that selectivity of the growth of the film has been lost, when the temperature changes from a predetermined value or changes from a predetermined angle in a graph showing change of the temperature during film formation, and changing the film formation condition; and
selectively growing the film on the surface of the semiconductor substrate by using the changed film formation condition, while measuring the temperature of the surface of the semiconductor substrate by using the pyrometer.

5. A method according to claim 4, wherein the film is grown by single wafer chemical vapor deposition.

6. A method according to claim 4, wherein the emissivity is measured by further using a second pyrometer which faces a backside of a susceptor on which the semiconductor substrate is placed.

7. A method according to claim 4, wherein the film formation condition includes at least one of a temperature, a flow rate of a source gas for film formation, a flow rate of an etching gas for preventing formation of a film on an unselected region, a carrier gas for evenly dispersing the source gas and etching gas, and a pressure.

8. A method according to claim 4, wherein when the film is selectively grown by using the changed film formation condition, said method comprises:
returning the film formation condition to the initial value if the temperature has returned to an initial value when selectivity is maintained; and
selectively growing the film on the surface of the semiconductor substrate by using the initial value of the film formation condition, while measuring the temperature of the surface of the semiconductor substrate by using the pyrometer.

9. A method according to claim 7, wherein when the film is selectively grown by using the changed film formation condition, said method comprises:
returning the film formation condition to the initial value if the temperature has returned to a value when selectivity is maintained; and
selectively growing the film on the surface of the semiconductor substrate by using the initial value of the film formation condition, while measuring the temperature of the surface of the semiconductor substrate by using the pyrometer.

10. A method according to claim 4, wherein when the film formation condition is changed, a ratio A/B of a flow rate A of the source gas to a flow rate B of the etching gas is decreased, or a film formation temperature is decreased.

11. A method according to claim 8, wherein when the film formation condition is changed, a ratio A/B of a flow rate A of the source gas to a flow rate B of the etching gas is decreased, or a film formation temperature is decreased.

12. A method according to claim 9, wherein when the film formation condition is changed, a ratio A/B of a flow rate A of the source gas to a flow rate B of the etching gas is decreased, or a film formation temperature is decreased.

13. A semiconductor device fabrication method of selectively growing a film in a predetermined region on a semiconductor substrate, comprising:
selectively growing the film on a surface of the semiconductor substrate by using a preset film formation condition, while measuring temperature of the surface of the semiconductor substrate by at least one pyrometer placed in a non-contact state above the surface of the semiconductor substrate, measuring an incubation period before nuclei are formed on an unselected region, and also measuring a film thickness A of the film formed on a selected region during the incubation period;
calculating the number M of cycles by dividing a desired film thickness T by the film thickness A; and
performing a film formation process by repeating, by the number M of cycles, performing film formation until the incubation period expires, stopping the film formation, and selectively growing the film on the surface of the semiconductor substrate by changing the film formation condition.

14. A method according to claim 13, wherein the film is grown by single wafer chemical vapor deposition.

15. A method according to claim 13, wherein the temperature is measured by further using a second pyrometer which faces a backside of a susceptor on which the semiconductor substrate is placed.

16. A method according to claim 13, wherein the film formation condition includes at least one of a temperature, a flow rate of a source gas for film formation, a flow rate of an etching gas for preventing formation of a film on an unselected region, a carrier gas for evenly dispersing the source gas and etching gas, and a pressure.

17. A method according to claim 1, wherein the film is one of a single-crystal film, polycrystalline film, and amorphous film containing at least one of Si, Ge, and C.

18. A method according to claim 4, wherein the film is one of a single-crystal film, polycrystalline film, and amorphous film containing at least one of Si, Ge, and C.

19. A method according to claim 13, wherein the film is one of a single-crystal film, polycrystalline film, and amorphous film containing at least one of Si, Ge, and C.
